(19) United States
(12) Patent Application Publication
(10) Pub. No.: US 2023/0160944 A1
(43) Pub. Date: May 25, 2023

(54) Reliability Macros for Contact Over Active Gate Layout Designs

(71) Applicant: International Business Machines Corporation, Armonk, NY (US)

(72) Inventors: Huimei ZHOU, Albany, NY (US); Ruilong XIE, Niskayuna, NY (US); Miaomiao WANG, Albany, NY (US)

(21) Appl. No.: 17/534,629

(22) Filed: Nov. 24, 2021

(51) Int. Cl. G01R 31/26; H01L 23/528; H01L 21/768; H01L 21/762

(52) U.S. Cl. CPC G01R 31/2601; H01L 23/528; H01L 21/76819; H01L 21/76224; H01L 23/5226

(57) ABSTRACT

Reliability test macros for contact over active gate (COAG) layout designs are provided. In one aspect, a COAG layout design reliability test macro includes: gate-shaped dielectric structures disposed over an active area of a substrate; source/drain regions present on opposite sides of the gate-shaped dielectric structures; source/drain contacts in direct contact with the source/drain regions; a dielectric fill material disposed on the source/drain contacts; and gate contacts present over, and in direct contact with, the gate-shaped dielectric structures in the active area, wherein the dielectric fill material is present in between the gate contacts and the source/drain contacts. Methods of forming and using the present COAG layout design reliability test macros are also provided.

### FIELD OF THE INVENTION

The present invention relates to contact over active gate (COAG) layout designs, and more particularly, to reliability macros for COAG layout designs and techniques for fabrication thereof.

### BACKGROUND OF THE INVENTION

Scalability is an important factor for the advancement of complementary metal-oxide semiconductor (CMOS) field-effect transistor (FET) device technology. Scaling can reduce the cell area, thereby permitting the device density (i.e., the number of devices per unit area) to be increased.

A contact over active gate (COAG) layout design can be used to increase the device density. As its name implies, a COAG design places the gate contact over the active area of the FET, rather than off to the side. While this arrangement serves to reduce the footprint of the device, there are however some notable middle-of-line (MOL) challenges associated with implementing a COAG design.

For instance, having the gate contact over the active area of the device places it closer to the source/drain region contacts. This configuration can limit whole circuit lifetime when the material above the source/drain region is not robust enough to supply operation voltage for the lifetime of the circuit due to breakdown. Breakdown occurs when the gate oxide loses its insulating properties due to the formation of conductive paths through the material. However, it is difficult to evaluate robustness of the material and the process used for COAG fabrication using typical structure designs for failure analysis.

Test structures (also referred to herein as test ‘macros’) can be used to evaluate the characteristics of a semiconductor device design. Being able to characterize the properties of a device design before that design is implemented in large scale production advantageously avoids having to implement costly reworks in the process flow, and greatly increases production yield.

Accordingly, effective reliability test macros for COAG layout designs would be desirable.

### SUMMARY OF THE INVENTION

The present invention provides reliability test macros for contact over active gate (COAG) layout designs. In one aspect of the invention, a COAG layout design reliability test macro is provided. The COAG layout design reliability test macro includes: gate-shaped dielectric structures disposed over an active area of a substrate; source/drain regions present on opposite sides of the gate-shaped dielectric structures; source/drain contacts in direct contact with the source/drain regions; a dielectric fill material disposed on the source/drain contacts; and gate contacts present over, and in direct contact with, the gate-shaped dielectric structures in the active area, wherein the dielectric fill material is present in between the gate contacts and the source/drain contacts.

In another aspect of the invention, a method of forming a COAG layout design reliability test macro is provided. The method includes: forming sacrificial gates over an active area of a substrate; forming source/drain regions on opposite sides of the sacrificial gates; burying the sacrificial gates and the source/drain regions in an interlayer dielectric (ILD); selectively removing the sacrificial gates forming gate trenches in the ILD; forming gate-shaped dielectric structures in the gate trenches; forming source/drain contacts in direct contact with the source/drain regions; depositing a dielectric fill material on the source/drain contacts; and forming gate contacts over, and in direct contact with, the gate-shaped dielectric structures in the active area, wherein the dielectric fill material is present in between the gate contacts and the source/drain contacts.

In yet another aspect of the invention, a method of evaluating a COAG layout design is provided. The method includes: providing a reliability test macro having gate-shaped dielectric structures disposed over an active area of a substrate; source/drain regions present on opposite sides of the gate-shaped dielectric structures; source/drain contacts in direct contact with the source/drain regions; a dielectric fill material disposed on the source/drain contacts; gate contacts present over, and in direct contact with, the gate-shaped dielectric structures in the active area, wherein the dielectric fill material is present in between the gate contacts and the source/drain contacts; applying a voltage V to at least one of the gate contacts; and detecting current between the gate contacts and the source/drain contacts due to breakdown or leakage of the dielectric fill material.

A more complete understanding of the present invention, as well as further features and advantages of the present invention, will be obtained by reference to the following detailed description and drawings.

### BRIEF DESCRIPTION OF THE DRAWINGS

FIG. 1 is a top-down diagram illustrating an orientation of the A-A′ and B-B′ cross-sectional views shown in the figures according to an embodiment of the present invention;

FIG. 2 is an A-A′ cross-sectional view illustrating fins having been patterned in a substrate according to an embodiment of the present invention;

FIG. 3 is a B-B′ cross-sectional view illustrating sacrificial gates having been formed on the fins, gate spacers having been formed alongside the sacrificial gates, source/drain regions having been formed in the fins on opposite sides of the sacrificial gates, and the sacrificial gates/gate spacers and source/drain regions having been buried in a (first) interlayer dielectric (ILD) according to an embodiment of the present invention;

FIG. 4 is a B-B′ cross-sectional view illustrating the sacrificial gates having been selectively removed forming gate trenches in the first ILD in between the gate spacers according to an embodiment of the present invention;

FIG. 5 is a B-B′ cross-sectional view illustrating a recess etch of the fins having been performed at the bottoms of the gate trenches to create cuts in the fins according to an embodiment of the present invention;

FIG. 6 is a B-B′ cross-sectional view illustrating a dielectric having been deposited into, and filling, the gate trenches and the cuts in the fins to form gate-shaped dielectric structures in the gate trenches and an isolation region in the fins below the gate-shaped dielectric structures according to an embodiment of the present invention;

FIG. 7 is a B-B′ cross-sectional view illustrating source/drain contact trenches having been patterned in the first ILD over the source/drain regions according to an embodiment of the present invention;

FIG. 8 is a B-B′ cross-sectional view illustrating source/drain contacts having been formed in the source/drain contact trenches over, and in direct contact with, the source/drain regions according to an embodiment of the present invention;

FIG. 9 is a B-B′ cross-sectional view illustrating a recess etch of the source/drain contacts having been performed to create gaps between the gate-shaped dielectric structures over the (recessed) source/drain contacts according to an embodiment of the present invention;

FIG. 10 is a B-B′ cross-sectional view illustrating a dielectric fill material having been deposited into, and filling, the gaps over the source/drain contacts according to an embodiment of the present invention;

FIG. 11 is a B-B′ cross-sectional view illustrating a (second) ILD having been deposited over the dielectric fill material and gate spacers/gate-shaped dielectric structures, and gate contacts having been formed in the second ILD over, and in direct contact with, the gate-shaped dielectric structures according to an embodiment of the present invention;

FIG. 12 is a three-dimensional schematic view of one of the source/drain contacts/gate contacts, and the dielectric fill material therebetween according to an embodiment of the present invention;

FIG. 13 is a top-down diagram illustrating an orientation of the gate contacts and source/drain contacts relative to the fins and gate-shaped dielectric structures according to an embodiment of the present invention;

FIG. 14 is a B-B′ cross-sectional view which follows from FIG. 4 illustrating, according to an alternative embodiment, a dielectric having been deposited into, and filling, the gate trenches to form gate-shaped dielectric structures in the gate trenches according to an embodiment of the present invention;

FIG. 15 is a B-B′ cross-sectional view illustrating source/drain contact trenches having been patterned in the first ILD over the source/drain regions according to an embodiment of the present invention;

FIG. 16 is a B-B′ cross-sectional view illustrating source/drain contacts having been formed in the source/drain contact trenches over, and in direct contact with, the source/drain regions according to an embodiment of the present invention;

FIG. 17 is a B-B′ cross-sectional view illustrating a recess etch of the source/drain contacts having been performed to create gaps between the gate-shaped dielectric structures over the (recessed) source/drain contacts according to an embodiment of the present invention;

FIG. 18 is a B-B′ cross-sectional view illustrating a dielectric fill material having been deposited into, and filling, the gaps over the source/drain contacts according to an embodiment of the present invention;

FIG. 19 is a B-B′ cross-sectional view illustrating a (third) ILD having been deposited over the dielectric fill material and gate spacers/gate-shaped dielectric structures, and gate contacts having been formed in the third ILD over, and in direct contact with, the gate-shaped dielectric structures according to an embodiment of the present invention;

FIG. 20 is a three-dimensional schematic view of one of the source/drain contacts/gate contacts, and the dielectric fill material therebetween according to an embodiment of the present invention;

FIG. 21 is a top-down diagram illustrating an orientation of the gate contacts and source/drain contacts relative to the fins and gate-shaped dielectric structures according to an embodiment of the present invention;

FIG. 22 is a diagram illustrating an exemplary methodology for evaluating a contact over active gate (COAG) layout design using the present reliability test macros according to an embodiment of the present invention; and

FIG. 23 is a three-dimensional schematic view, according to another alternative embodiment, of a bottom source/drain contact, a gate contact, and the dielectric fill material therebetween according to an embodiment of the present invention.

### DETAILED DESCRIPTION OF PREFERRED EMBODIMENTS

As provided above, reliability concerns related to gate oxide breakdown and leakage are associated with contact over active gate (COAG) layout designs which place the gate contact over the active area of the device, closer to the source/drain region contacts. As also provided above, test macros can be used to characterize and evaluate the properties of a particular device design prior to implementing the design in large scale manufacture. Use of such test macros helps to avoid costly rework of the design at the production level, and boosts production yield. To date, however, there are no test macros known to exist that enable testing of the material properties of COAG layout designs to evaluate, e.g., leakage and gate oxide breakdown in the design.

Advantageously, provided herein are reliability test macros and techniques for fabrication and use thereof for evaluating COAG layout designs and, in particular, the material properties of the dielectric separating the gate contact from the source/drain region contacts to determine the robustness of the material against breakdown/leakage. As will be described in detail below, the present test macro designs employ a fin cut or gate cut to simulate isolation of the gate workfunction-setting metal.

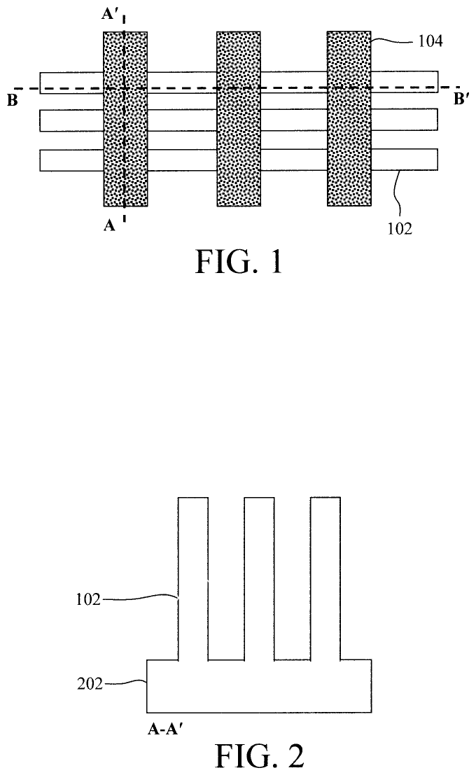

An exemplary methodology for forming a reliability test macro for a COAG layout design in accordance with the present techniques is now described by way of reference to FIGS. 1-13. In this present example, a fin field-effect transistor (FET) architecture will be used to illustrate the present reliability test macro design. However, it is to be understood that the present techniques are applicable to any type of planar and non-planar device design including, but not limited to, finFET, nanowire/nanosheet FET, etc. designs.

FIG. 1 is a top-down diagram illustrating an orientation of the cross-sectional views that will be shown in the figures. Namely, the cross-sectional views that will be described below represent cuts through the test macro structure along line A-A′, line B-B′ or line C-C′. As described above, the present, non-limiting example involves finFET architecture and, as shown in FIG. 1, the cross-sectional views A-A′ will depict cuts along one of a plurality of sacrificial gates 104 (which are related to a gate-last process—see below), through each of a plurality of fins 102. The cross-sectional views B-B′ will depict cuts along a given one of the fins 102, through each of the sacrificial gates 104. As shown in FIG. 1, the sacrificial gates 104 are disposed over the fins 102, with the sacrificial gates 104 oriented perpendicular to the fins 102.

In general, fabrication of the present reliability test macro design begins with the formation of an active area of the test structure on a substrate whether it be a semiconductor layer patterned into an active area, the formation of a nanowire(s) and/or nanosheet(s) or, as in the present example, with the patterning of a plurality of the fins 102 in a substrate 202. See FIG. 2 (a cross-sectional view A-A′).

According to an exemplary embodiment, substrate 202 is a bulk semiconductor wafer, such as a bulk silicon (Si), bulk germanium (Ge), bulk silicon germanium (SiGe) and/or bulk III-V semiconductor wafer. Alternatively, substrate 202 can be a semiconductor-on-insulator (SOI) wafer. A SOI wafer includes a SOI layer separated from an underlying substrate by a buried insulator. When the buried insulator is an oxide it is also referred to herein as a buried oxide or BOX. The SOI layer can include any suitable semiconductor material(s), such as Si, Ge, SiGe and/or a III-V semiconductor. Further, substrate 202 may already have pre-built structures (not shown) such as transistors, diodes, capacitors, resistors, interconnects, wiring, etc.

Standard lithography and etching techniques can be used to pattern the fins 102 in the substrate 202. With standard lithography and etching techniques, a lithographic stack (not shown), e.g., photoresist/organic planarizing layer (OPL)/anti-reflective coating (ARC), is used to pattern a fin hardmask (not shown) with the footprint and location of each of the fins 102. Suitable fin hardmask materials include, but are not limited to, nitride hardmask materials such as silicon nitride (SiN), silicon oxynitride (SiON) and/or silicon carbide nitride (SiCN). A directional (i.e., anisotropic) etching process such as reactive ion etching (RIE) is then employed to transfer the pattern from the fin hardmask to the substrate 202, forming the fins 102 in the substrate 202. Alternatively, the fin hardmask can be formed by other suitable techniques, including but not limited to, sidewall image transfer (SIT), self-aligned double patterning (SADP), self-aligned quadruple patterning (SAQP), and other self-aligned multiple patterning (SAMP). As shown in FIG. 2, the as-patterned fins 102 extend partway through the substrate 202.

A plurality of the above-referenced sacrificial gates 104 are then formed on the fins 102. See FIG. 3 (a cross-sectional view B-B′). It is notable that the number of fins 102 and/or the number of sacrificial gates 104 shown in the figures is merely an example being provided to illustrate the present techniques, and that embodiments are contemplated herein where more or fewer fins 102 and/or sacrificial gates 104 than shown are present, including embodiments where a single fin 102 and/or a single sacrificial gate 104 is employed. Suitable materials for the sacrificial gates 104 include, but are not limited to, poly-silicon (poly-Si) and/or amorphous silicon (a-Si) which can be deposited using a process such as chemical vapor deposition (CVD), atomic layer deposition (ALD) or physical vapor deposition (PVD). Standard lithography and etching techniques (see above) can then be employed to pattern the sacrificial gate material into the individual sacrificial gates 104 shown in FIG. 3. According to an exemplary embodiment, a thin (e.g., from about 1 nanometer (nm) to about 3 nm and ranges therebetween) layer of silicon oxide (SiOx) (not shown) is first formed on the fins 102, followed by the poly-Si and/or a-Si.

Sacrificial gates 104 are being used to emulate the starting device structure of a gate-last process for semiconductor field-effect transistor (FET) device fabrication. The term ‘sacrificial’ as used herein generally refers to any structure that is removed, in whole or in part, during fabrication of the test macro. With a gate-last process for semiconductor FET device fabrication, sacrificial gates (such as sacrificial gates 104) are formed early on in the fabrication flow and serve as placeholders during source/drain region formation. Later on, the sacrificial gates are removed and replaced with the final gates of the device. Doing so advantageously avoids exposing the materials of these ‘replacement’ gates to potentially damaging conditions such as the high temperatures employed during formation of the source/drain regions. For instance, replacement metal gate (RMG) stacks can employ a high-κ material as a gate dielectric. The term “high-κ” as used herein refers to a material having a relative dielectric constant κ which is much higher than that of silicon dioxide (e.g., a dielectric constant κ is about 25 for hafnium oxide (HfO₂) rather than 3.9 for SiO₂). High-κ materials can become damaged by high temperature anneals. Thus, by forming the gate late in the process, any potential for high temperature damage of the gate stack materials can be avoided altogether.

As will become apparent from the description that follows, the purpose of the present reliability test macro is not to provide a fully functioning transistor, but instead to evaluate the properties of the materials in a COAG layout design and the associated fabrication process for leakage and gate oxide breakdown concerns. Thus, it is notable that fabrication of the present reliability test macro will not involve replacement of the sacrificial gates 104 with conductive gates (as in a standard FET fabrication process flow) but with a dielectric instead. The notion here is that use of a robust dielectric in place of the gate materials will avoid introducing additional reliability concerns (i.e., other breakdown and leakage sources) to the macro test structure. That way, the evaluation can focus on the material properties attributable to the COAG layout specifically, such as the insulator separating the gate contact (which is over the active area of the device) from the source/drain region contacts. To look at it another way, if a traditional gate stack including a gate dielectric (see above) were used in the test macro, then it would be difficult to pinpoint the source of the oxide breakdown since the gate dielectric, itself also an oxide, too can be a source of breakdown and leakage.

Reference will be made herein to ‘cuts’ or patterning of the gates and/or fins being made to isolate the gate contacts to a given device. For instance, as highlighted above, the sacrificial gates 104 are oriented perpendicular to the fins 102 in the present reliability test macro. Thus, referring briefly back to FIG. 1, if for instance patterning was used to remove (i.e., cut) the center sacrificial gate 104 (not shown) which can then be replaced with a dielectric, this would serve to isolate the sacrificial gate 104 shown on the left from the sacrificial gate 104 shown in the right. Likewise, patterning the fins 102 to create cuts (not shown) in the fins 102 beneath the (cut/removed) center sacrificial gate 104 (that has been cut/removed) which too will be filled with the dielectric would serve to isolate the sacrificial gate 104 shown on the left from the sacrificial gate 104 shown in the right. Depictions of these gate and fin cuts will be provided and described in detail in conjunction with the description of the fabrication of the present reliability test macro below.

Referring again to FIG. 3, gate spacers 302 are then formed alongside the sacrificial gates 104. Suitable materials for the gate spacers 302 include, but are not limited to, oxide spacer materials such as SiOx and/or silicon oxycarbide (SiOC) and/or nitride spacer materials such as silicon nitride (SiN), silicon-boron-nitride (SiBN), siliconborocarbonitride (SiBCN) and/or silicon oxycarbonitride (SiOCN), which can be deposited onto the sacrificial gates 104 using a process such as CVD, ALD or PVD. A directional (i.e., anisotropic) etching process such as RIE can then be employed to pattern the gate spacer material into the individual gate spacers 302 shown in FIG. 3. According to an exemplary embodiment, the gate spacers 302 have a thickness of from about 3 nm to about 15 nm and ranges therebetween.

Source/drain regions 304 are next formed in the fins 102 on opposite sides of the sacrificial gates 104. The gate spacers 302 offset the source/drain regions 304 from the sacrificial gates 104. According to an exemplary embodiment, source/drain regions 304 are formed from an in-situ doped (i.e., where a dopant(s) is introduced during growth) or ex-situ doped (e.g., where a dopant(s) is introduced by ion implantation) epitaxial material such as epitaxial Si, epitaxial SiGe, etc. grown on the fins 102 at the base of the sacrificial gates 104. Suitable n-type dopants include, but are not limited to, phosphorous (P) and/or arsenic (As). Suitable p-type dopants include, but are not limited to, boron (B).

The sacrificial gates 104/gate spacers 302 and source/drain regions 304 are then buried in an interlayer dielectric (ILD) 306. Suitable ILD 306 materials include, but are not limited to, oxide materials such as SiOx and/or organosilicate glass (SiCOH) and/or ultralow-κ interlayer dielectric (ULK-ILD) materials, e.g., having a dielectric constant κ of less than 2.7. Suitable ultralow-κ dielectric materials include, but are not limited to, porous organosilicate glass (pSiCOH). A process such as CVD, ALD, or PVD can be used to deposit the ILD 306. Following deposition, the ILD 306 can be polished down to the top surface of the sacrificial gates 104/gate spacers 302 using a process such as chemical-mechanical polishing (CMP). Doing so will enable the selective removal of the sacrificial gates 104 according to the above-described gate-last process.

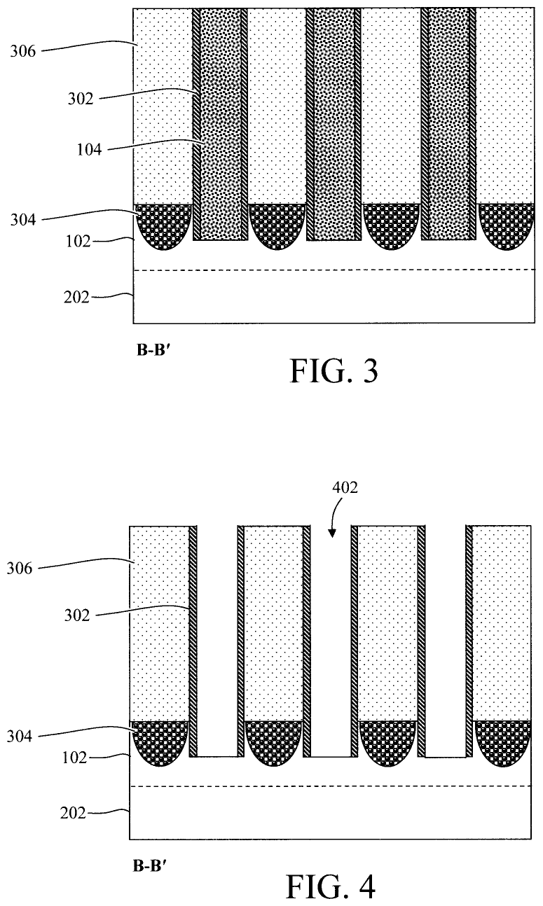

Namely, the sacrificial gates 104 are next selectively removed. See FIG. 4 (a cross-sectional view B-B′). As provided above, the term ‘gate cut’ is also used herein when referring to the patterning/removal of one or more of the sacrificial gates 104. In the present example, each of the sacrificial gates 104 is removed and subsequently replaced with a robust dielectric over which gate contacts will be formed (see below). Doing so advantageously isolates each of the gate contacts to a particular device.

According to an exemplary embodiment, the sacrificial gates 104 are selectively removed using a poly-Si and/or a-Si selective etching process. As shown in FIG. 4, removal of the sacrificial gates 104 forms gate trenches 402 in the ILD 306 in between the gate spacers 302.

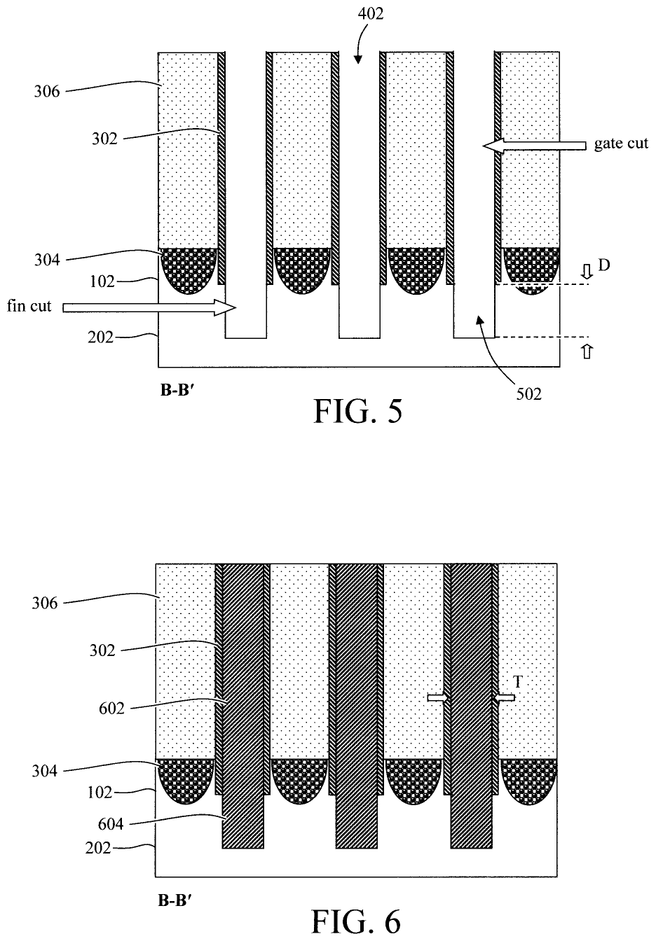

As also provided above, patterning cuts in the fins 102 (i.e., ‘fin cuts’) can also be performed to further isolate the gate contacts to a particular device. Thus, in the instant example, a recess etch of the fins 102 at the bottoms of the gate trenches 402, in between the gate spacers 302, is performed thereby creating cuts 502 in the fins 102. See FIG. 5 (a cross-sectional view B-B′). It is notable, however, that use of a fin cut in the present reliability test macro design is optional, and embodiments are contemplated herein and described in detail below where only a gate cut (i.e., removal of the sacrificial gates 104) is performed.

By way of example only, the recess etch of the fins 102 can be performed using a non-directional (i.e., isotropic) etching process such as a wet chemical etch or a gas phase etch. As shown in FIG. 5, the cuts 502 in the fins 102 extend below the gate trenches 402 and gate spacers 302 (i.e., the gate spacers 302 are present along only the sidewalls of the gate trenches 402). According to an exemplary embodiment, the cuts 502 in the fins 102 have a depth D (i.e., below the gate spacers 302) of from about 5 nm to about 100 nm and ranges therebetween.

As described in detail above, the goal here is not to replace the sacrificial gates 104 with traditional gate stacks, but instead to use a robust dielectric material to avoid introducing any additional sources of breakdown or leakage, such as might be the case if a traditional gate dielectric was used (see above). Thus, a dielectric is next deposited into, and filling, the gate trenches 402 and the cuts 502 in the fins 102 to form (gate-shaped) dielectric structures 602 in the gate trenches 402 and an isolation region 604 in the fins 102 below the gate-shaped dielectric structures 602. See FIG. 6 (a cross-sectional view B-B′). Suitable dielectric materials include, but are not limited to, SiOx and/or SiN, which can be deposited into, and filling, the gate trenches 402 and the cuts 502 in the fins 102 using a process such as CDV, ALD or PVD. Following deposition, excess dielectric material can be removed using a process such as CMP. Based on this process, the gate-shaped dielectric structures 602 and the isolation region 604 will be formed from the same material. According to an exemplary embodiment, the gate-shaped dielectric structures 602 each has a thickness T of from about 5 nm to about 200 nm and ranges therebetween. At such thicknesses, the gate-shaped dielectric structures 602 are robust and will not be a contributing factor to breakdown or leakage concerns. As shown in FIG. 6, gate spacers 302 are disposed alongside the gate-shaped dielectric structures 602 and serve to offset the source/drain regions 304 from the gate-shaped dielectric structures 602.

By ‘gate-shaped’ it is meant that the gate-shaped dielectric structures 602 generally have a rectangular cross-sectional profile with one sidewall of the gate-shaped dielectric structures 602 directly contacting one gate spacer 302 and another, opposite sidewall of the gate-shaped dielectric structures 602 directly contacting another gate spacer 302. Further, the gate-shaped dielectric structures 602 formed by this process can each be configured as a solid dielectric in between pairs of the gate spacers 302, i.e., without any intervening gaps and/or non-dielectric layers/structures.

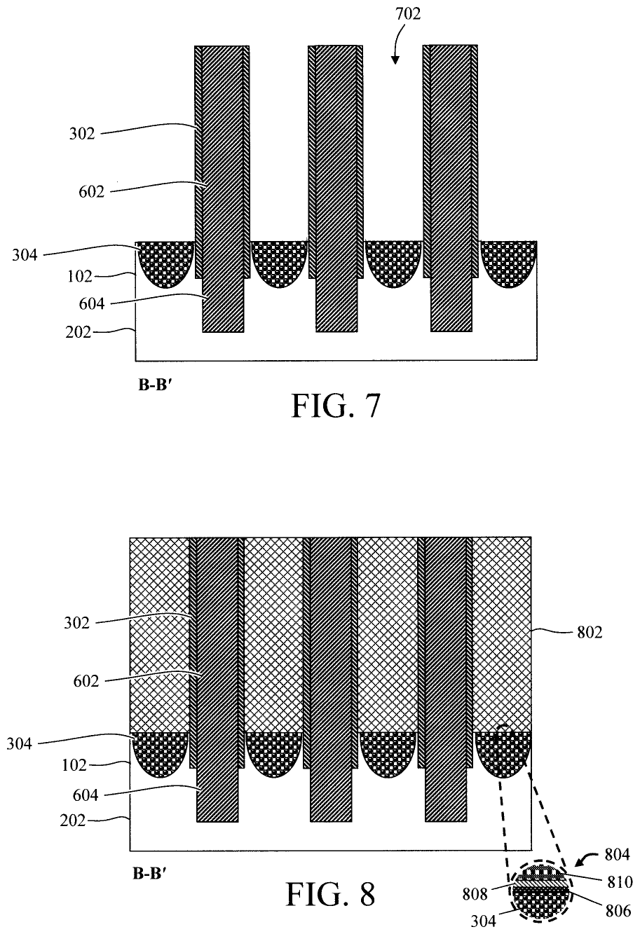

Standard lithography and etching techniques (see above) are then used to pattern source/drain contact trenches 702 in the ILD 306 over the source/drain regions 304. See FIG. 7 (a cross-sectional view B-B′). By way of example only, an oxide-selective etching such as an oxide-selective RIE can be employed for the source/drain contact trench 702 etch. As shown in FIG. 7, the gate spacers 302 are present along the sidewalls of the source/drain contact trenches 702.

Source/drain contacts 802 are then formed in the source/drain contact trenches 702 over, and in direct contact with, the source/drain regions 304. See FIG. 8 (a cross-sectional view B-B′). As shown in magnified view 804, according to a non-limiting example, each of the source/drain contacts 802 can include, a silicide liner 806 lining the source/drain contact trenches 702, an (optional) adhesion/barrier layer 808 disposed on the silicide liner 806, and a conductive fill metal 810 disposed on the adhesion/barrier layer 808 (or directly on silicide liner 806 when the optional adhesion/barrier layer 808 is not present). Suitable materials for the silicide liner 806 include, but are not limited to, titanium (Ti), nickel (Ni) and/or alloys such as nickel platinum (NiPt). Suitable materials for the adhesion/barrier layer 808 include, but are not limited to, tantalum (Ta), tantalum nitride (TaN), titanium (Ti) and/or titanium nitride (TiN). The use of an adhesion/barrier layer 808 helps to prevent diffusion of the source/drain contact metals into the surrounding dielectric. Suitable conductive fill metals 810 include, but are not limited to, copper (Cu), tungsten (W), ruthenium (Ru) and/or cobalt (Co). The silicide liner 806, adhesion/barrier layer 808 and conductive fill metal 810 can be deposited into the source/drain contact trenches 702 using a process such as evaporation, sputtering, ALD, CVD or electrochemical plating. Additionally, a seed layer (not shown) can be deposited into and lining the source/drain contact trenches 702 prior to metal deposition, i.e., to facilitate plating of the metal. Following deposition, excess metal can be removed using a process such as CMP. Accordingly, at this stage in the process, the tops of the source/drain contacts 802 are coplanar with the tops of the gate-shaped dielectric structures 602. See FIG. 8.

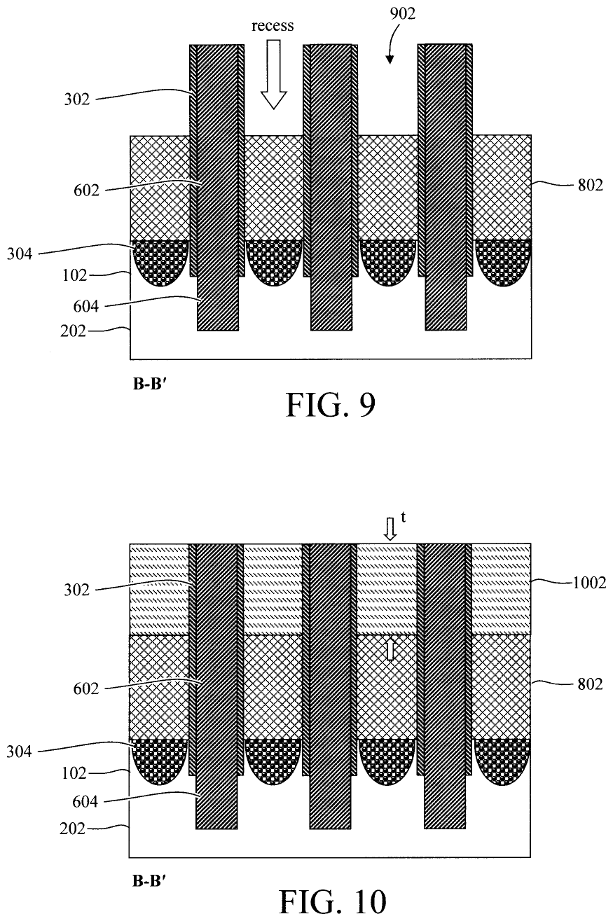

However, a recess etch of the source/drain contacts 802 is next performed. See FIG. 9 (a cross-sectional view B-B′). A directional (i.e., anisotropic) etching process such as RIE can be employed for the recess etch of the source/drain contacts 802. As shown in FIG. 9, the tops of the (recessed) source/drain contacts 802 are now below the tops of the gate-shaped dielectric structures 602, creating gaps 902 between the gate-shaped dielectric structures 602 over the (recessed) source/drain contacts 802.

A dielectric fill material 1002 is then deposited into, and filling, the gaps 902 over the source/drain contacts 802. See FIG. 10 (a cross-sectional view B-B′). Suitable dielectric fill materials 1002 include, but are not limited to, SiOx, silicon carbide (SiC), SiOCN, SiN and/or SiCOH, which can be deposited using a process such as CVD, ALD or PVD. Following deposition, excess dielectric fill material 1002 can be removed using a process such as CMP. Doing so will expose the gate spacers 302/gate-shaped dielectric structures 602 along the top surface of the dielectric fill material 1002 as shown in FIG. 10.

The dielectric fill material 1002 will separate the source/drain contacts 802 from the gate contacts (to be formed below). Thus, as provided above, it is the (breakdown/leakage) properties of this dielectric fill material 1002 that the present reliability test macro will be used to analyze. See, for example, the exemplary methodology for reliability testing using the present COAG test macro described in conjunction with the description of FIG. 22, below. According to an exemplary embodiment, the dielectric fill material 1002 has a thickness t of from about 5 nm to about 30 nm and ranges therebetween.

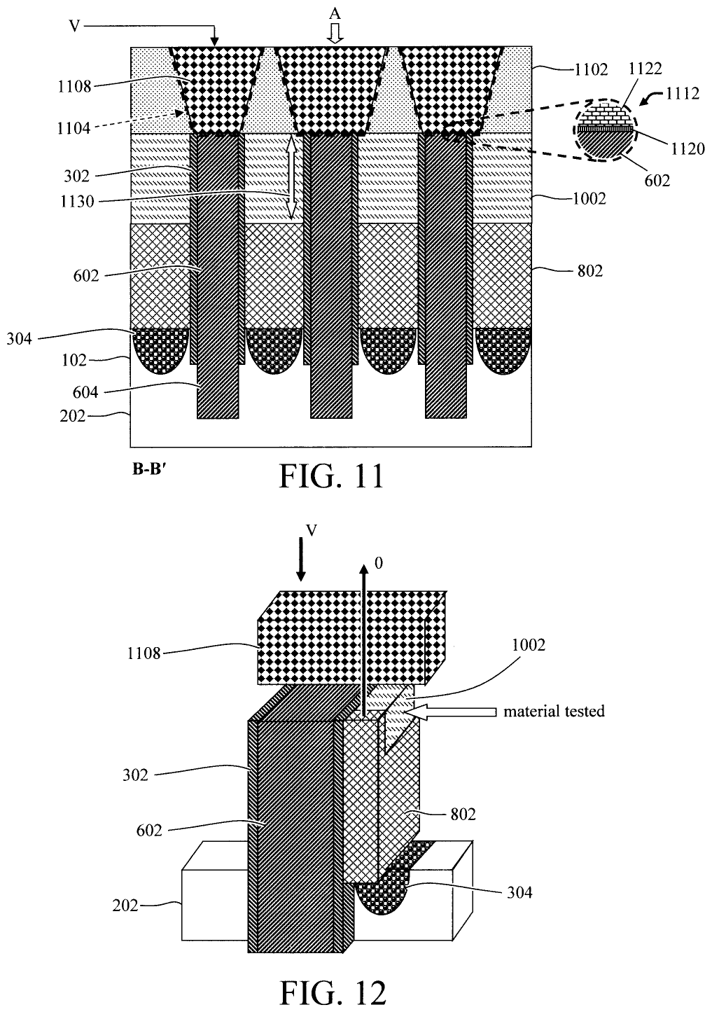

An ILD 1102 is then deposited over the dielectric fill material 1002 and gate spacers 302/gate-shaped dielectric structures 602. See FIG. 11 (a cross-sectional view B-B′). For clarity, the terms ‘first’ and ‘second’ may also be used herein when referring to ILD 306 and ILD 1102, respectively. Suitable ILD 1102 materials include, but are not limited to, oxide materials such as SiOx and/or SiCOH and/or ULK-ILD materials such as pSiCOH. A process such as CVD, ALD, or PVD can be used to deposit the ILD 1102. Following deposition, the ILD 1102 can be polished using a process such as CMP.

Gate contacts 1108 are then formed in the ILD 1102 over, and in direct contact with, the gate-shaped dielectric structures 602. To do so, standard lithography and etching techniques (see above) are first employed to pattern contact trenches 1104 (shown outlined with dashes) in ILD 1102 over the gate-shaped dielectric structures 602. The contact trenches 1104 are then filled with a metal or a combination of metals to form the gate contacts 1108. As shown in magnified view 1112, according to a non-limiting example, each of the gate contacts 1108 includes an (optional) adhesion/barrier layer 1120 lining the contact trenches 1104, and a conductive fill metal 1122 disposed on the adhesion/barrier layer 1120 (or directly into the contact trenches 1104 when the optional adhesion/barrier layer 1120 is not present). Suitable materials for the adhesion/barrier layer 1120 include, but are not limited to, Ta, TaN, Ti and/or TiN. As described above, the use of an adhesion/barrier layer helps to prevent diffusion of the contact metals into the surrounding dielectric. Suitable conductive fill metals 1122 include, but are not limited to, Cu, W, Ru and/or Co. The adhesion/barrier layer 1120 and conductive fill metal 1122 can be deposited into the contact trenches 1104 using a process such as evaporation, sputtering, ALD, CVD or electrochemical plating. Additionally, a seed layer (not shown) can be deposited into and lining the contact trenches 1104 prior to metal deposition, i.e., to facilitate plating of the metal. Following deposition, excess metal can be removed using a process such as CMP.

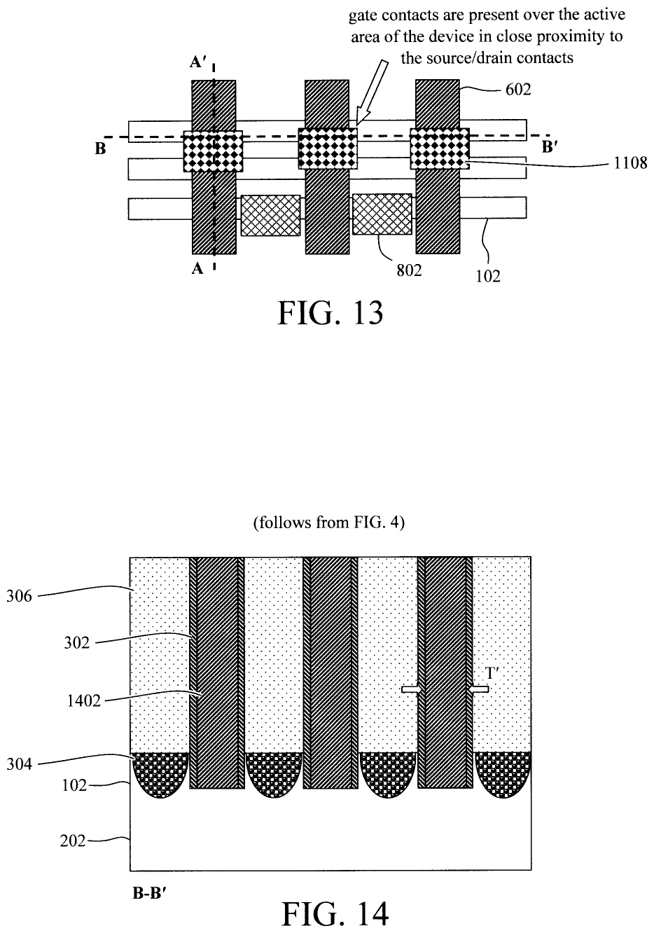

As highlighted above, of particular concern is the reliability of the dielectric material in between the source/drain contacts 802 and the gate contacts 1108 such as dielectric fill material 1002. See arrow 1130. As such, it is the (breakdown/leakage) properties of this dielectric fill material 1002 that the present reliability test macro will be used to analyze. This concept is further illustrated by way of reference to FIG. 12 which provides a three-dimensional schematic view of one of the source/drain contacts 802/gate contacts 1108, and the dielectric fill material 1002 therebetween. Components such as the ILD 1102 are not shown in FIG. 12 for ease and clarity of depiction. As shown in FIG. 12, a voltage V is applied to the gate contacts 1108 and the current, if any, between the source/drain contacts 802 and gate contacts 1108 (i.e., due to breakdown or leakage of the intervening dielectric fill material 1002) is detected at the source/drain contacts 802. For instance, the present COAG test macro can be used to analyze whether the thickness, composition, etc. of the dielectric fill material 1002 in a given design and associated manufacturing process is robust enough, or whether it breaks down or becomes too leaky. A detailed description of the process for reliability testing using the present COAG test macro is provided in conjunction with the description of FIG. 22, below.

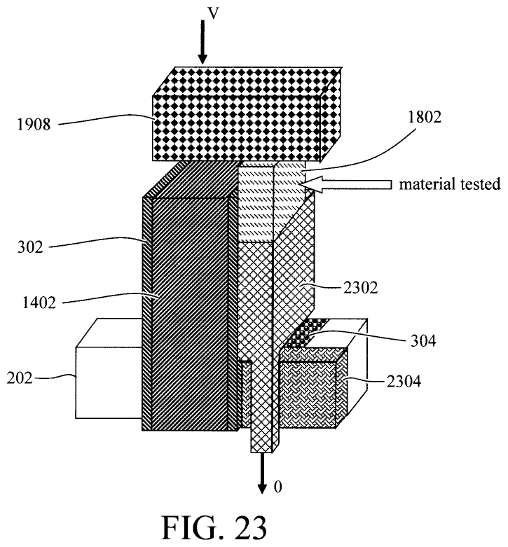

In this example, the source/drain contacts 802 are accessed from the top of the COAG test structure over the source/drain regions 304 in what is referred to herein as a ‘top source/drain contact configuration.’ For instance, see FIG. 12 where both the source/drain contacts 802 and gate contacts 1108 are accessed from the same (top) side of the COAG test structure. It is notable, however, that the implementation of a top source/drain contact configuration is merely an example, and configurations are contemplated herein where the source/drain contacts are accessed from the bottom of the COAG test structure—see, for example, FIG. 23 below.

FIG. 13 is a top-down diagram (i.e., from viewpoint A—See FIG. 11) illustrating an orientation of the gate contacts 1108 and source/drain contacts 802 relative to the fins 102 and gate-shaped dielectric structures 602. For clarity, the intervening layers/structures such as the dielectric fill material 1002, ILD 1102, etc. are not shown in FIG. 13. The orientation of the cross-sectional views A-A′ and B-B′ are also shown in FIG. 13 for clarity. As shown in FIG. 13, the present reliability test macro implements a COAG design whereby the gate contacts 1108 are placed over the active area of the device. Doing so, however, places the gate contacts 1108 in close proximity to the source/drain contacts 802. Advantageously, the present COAG test macro can be used to evaluate the reliability of this design.

As provided above, patterning cuts in the gates (i.e., ‘gate cuts’) and/or fins 102 (i.e., ‘fin cuts’) can be performed to isolate the gate contacts to a particular device. However, it has been found herein that employing a gate cut alone (i.e., removal of the sacrificial gates 104) provides sufficient isolation of the individual gate contacts for reliability testing. Thus, another exemplary methodology for forming a reliability test macro for a COAG layout design in accordance with the present techniques is now described by way of reference to FIGS. 14-21 where only a gate cut is performed. The orientations of the cross-sectional views shown in the following figures are the same as above. Thus, reference may be made to FIG. 1 above for a description of those cross-sectional views.

As in the previous example, a fin FET architecture will also be used here as an illustrative example. However, as provided above, it is to be understood that the present techniques are applicable to any type of planar and non-planar device design including, but not limited to, finFET, nanowire/nanosheet FET, etc. designs. The process begins in exactly the same manner as described in conjunction with the description of FIGS. 2 and 3, above. Namely, the fins 102 are patterned in the substrate 202, a plurality of sacrificial gates 104 are formed on the fins 102, gate spacers 302 are formed alongside the sacrificial gates 104, source/drain regions 304 are formed in the fins 102 on opposite sides of the sacrificial gates 104, the sacrificial gates 104/gate spacers 302 and source/drain regions 304 are buried in the ILD 306, and the sacrificial gates 104 are selectively removed forming gate trenches 402 in the ILD 306 in between the gate spacers 302. Thus, the structure shown in FIG. 14 follows from what is depicted in FIG. 4. Like structures are numbered alike in the figures.

Here, however, instead of next performing the above-described fin cuts 502, the dielectric is deposited into, and filling, the gate trenches 402 to form gate-shaped dielectric structures 1402 in the gate trenches 402. See FIG. 14 (a cross-sectional view B-B′). As provided above, suitable dielectric materials include, but are not limited to, SiOx and/or SiN, which can be deposited into, and filling, the gate trenches 402 using a process such as CDV, ALD or PVD. Following deposition, excess dielectric material can be removed using a process such as CMP. According to an exemplary embodiment, the gate-shaped dielectric structures 1402 each has a thickness T′ of from about 5 nm to about 200 nm and ranges therebetween. At such thicknesses, the gate-shaped dielectric structures 1402 are robust and will not be a contributing factor to breakdown or leakage concerns. As shown in FIG. 14, gate spacers 302 are disposed alongside the gate-shaped dielectric structures 1402 and serve to offset the source/drain regions 304 from the gate-shaped dielectric structures 1402.

As highlighted above, by ‘gate-shaped’ it is meant that the gate-shaped dielectric structures 1402 generally have a rectangular cross-sectional profile with one sidewall of the gate-shaped dielectric structures 1402 directly contacting one gate spacer 302 and another, opposite sidewall of the gate-shaped dielectric structures 1402 directly contacting another gate spacer 302. Further, the gate-shaped dielectric structures 1402 formed by this process can each be configured as a solid dielectric in between pairs of the gate spacers 302, i.e., without any intervening gaps and/or non-dielectric layers/structures.

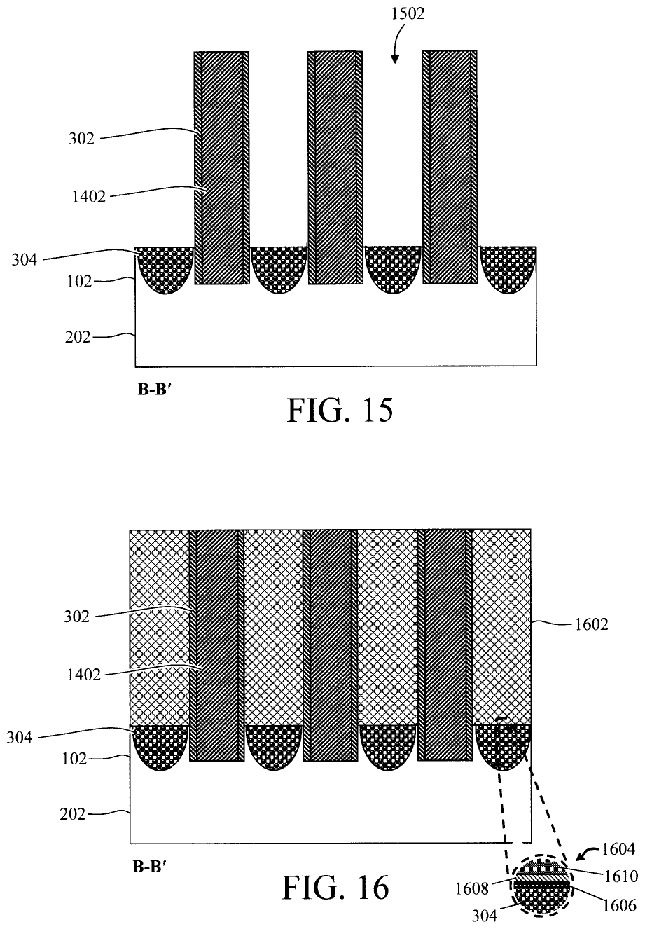

Standard lithography and etching techniques (see above) are then used to pattern source/drain contact trenches 1502 in the ILD 306 over the source/drain regions 304. See FIG. 15 (a cross-sectional view B-B′). By way of example only, an oxide-selective etching such as an oxide-selective RIE can be employed for the source/drain contact trench 1502 etch. As shown in FIG. 15, the gate spacers 302 are present along the sidewalls of the source/drain contact trenches 1502.

Source/drain contacts 1602 are then formed in the source/drain contact trenches 1502 over, and in direct contact with, the source/drain regions 304. See FIG. 16 (a cross-sectional view B-B′). As shown in magnified view 1604, according to a non-limiting example, each of the source/drain contacts 1602 includes a silicide liner 1606 lining the source/drain contact trenches 1502, an (optional) adhesion/barrier layer 1608 disposed on the silicide liner 1606, and a conductive fill metal 1610 disposed on the adhesion/barrier layer 1608 (or directly on silicide liner 1606 when the optional adhesion/barrier layer 1608 is not present). As provided above, suitable materials for the silicide liner 1606 include, but are not limited to, Ti, Ni and/or alloys such as NiPt. Suitable materials for the adhesion/barrier layer 1608 include, but are not limited to, Ta, TaN, Ti and/or TiN. The use of an adhesion/barrier layer 1608 helps to prevent diffusion of the source/drain contact metals into the surrounding dielectric. Suitable conductive fill metals 1610 include, but are not limited to, Cu, W, Ru and/or Co. The silicide liner 1606, adhesion/barrier layer 1608 and conductive fill metal 1610 can be deposited into the source/drain contact trenches 1502 using a process such as evaporation, sputtering, ALD, CVD or electrochemical plating. Additionally, a seed layer (not shown) can be deposited into and lining the source/drain contact trenches 1502 prior to metal deposition, i.e., to facilitate plating of the metal. Following deposition, excess metal can be removed using a process such as CMP. Accordingly, at this stage in the process, the tops of the source/drain contacts 1602 are coplanar with the tops of the gate-shaped dielectric structures 1402. See FIG. 16.

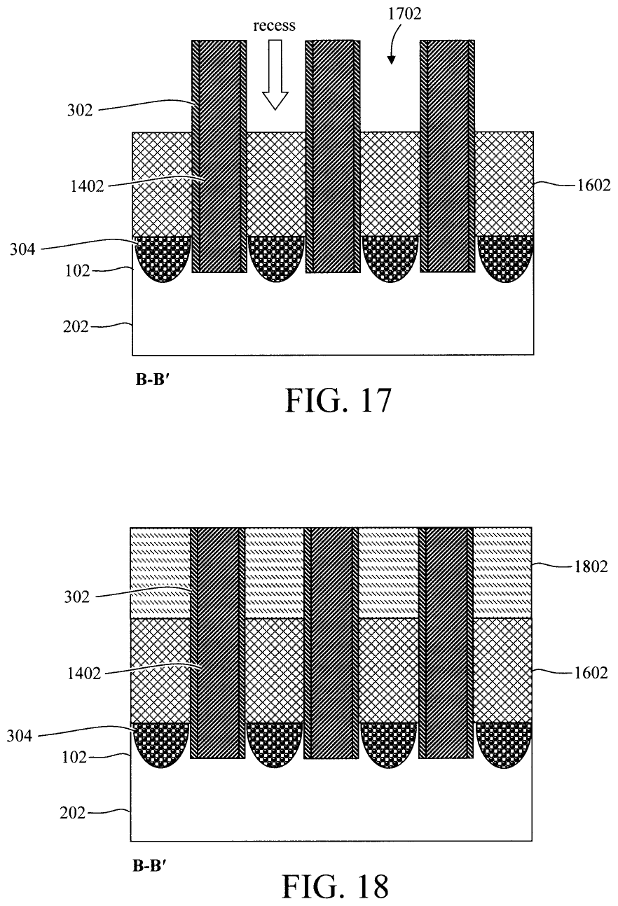

However, in the same manner as above, a recess etch of the source/drain contacts 1602 is next performed. See FIG. 17 (a cross-sectional view B-B′). A directional (i.e., anisotropic) etching process such as RIE can be employed for the recess etch of the source/drain contacts 1602. As shown in FIG. 17, the tops of the (recessed) source/drain contacts 1602 are now below the tops of the gate-shaped dielectric structures 1402, creating gaps 1702 between the gate-shaped dielectric structures 1402 over the (recessed) source/drain contacts 1602.

A dielectric fill material 1802 is then deposited into, and filling, the gaps 1702 over the source/drain contacts 1602. See FIG. 18 (a cross-sectional view B-B′). As provided above, suitable dielectric fill materials 1802 include, but are not limited to, SiOx, SiC, SiOCN, SiN and/or SiCOH, which can be deposited using a process such as CVD, ALD or PVD. Following deposition, excess dielectric fill material 1802 can be removed using a process such as CMP. Doing so will expose the gate spacers 302/gate-shaped dielectric structures 1402 along the top surface of the dielectric fill material 1802 as shown in FIG. 18.

The dielectric fill material 1802 will separate the source/drain contacts 1602 from the gate contacts (to be formed below). Thus, as provided above, it is the (breakdown/leakage) properties of this dielectric fill material 1802 that the present reliability test macro will be used to analyze. See, for example, the exemplary methodology for reliability testing using the present COAG test macro described in conjunction with the description of FIG. 22, below. According to an exemplary embodiment, the dielectric fill material 1802 has a thickness t of from about 5 nm to about 30 nm and ranges therebetween.

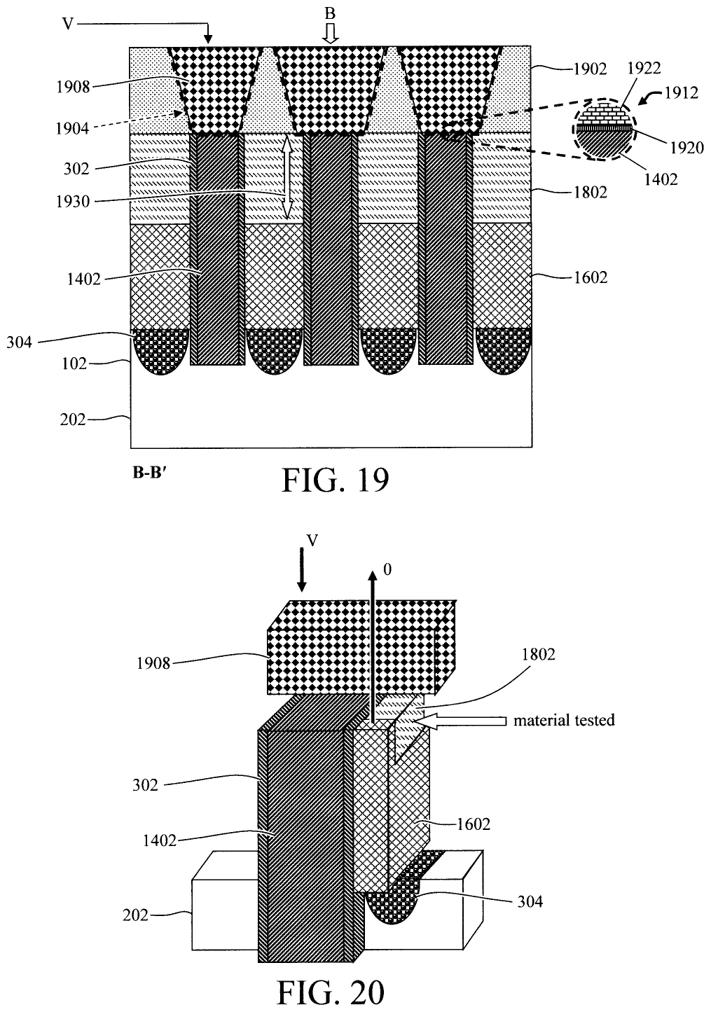

An ILD 1902 is then deposited over the dielectric fill material 1802 and gate spacers 302/gate-shaped dielectric structures 1402. See FIG. 19 (a cross-sectional view B-B′). For clarity, the term ‘third’ may also be used herein when referring to ILD 1902, so as to distinguish it from the ‘first’ ILD 306 and ‘second’ ILD 1102. As provided above, suitable ILD 1902 materials include, but are not limited to, oxide materials such as SiOx and/or SiCOH and/or ULK-ILD materials such as pSiCOH. A process such as CVD, ALD, or PVD can be used to deposit the ILD 1902. Following deposition, the ILD 1902 can be polished using a process such as CMP.

Gate contacts 1908 are then formed in the ILD 1902 over, and in direct contact with, the gate-shaped dielectric structures 1402. To do so, in the same manner as described above, standard lithography and etching techniques (see above) are first employed to pattern contact trenches 1904 (shown outlined with dashes) in ILD 1902 over the gate-shaped dielectric structures 1402. The contact trenches 1904 are then filled with a metal or a combination of metals to form the gate contacts 1908. As shown in magnified views 1912, according to a non-limiting example, each of the gate contacts 1908 includes an (optional) adhesion/barrier layer 1920 lining the contact trenches 1904, and a conductive fill metal 1922 disposed on the adhesion/barrier layer 1920 (or directly into the contact trenches 1904 when the optional adhesion/barrier layer 1920 is not present). As provided above, suitable materials for the adhesion/barrier layer 1920 include, but are not limited to, Ta, TaN, Ti and/or TiN. The use of an adhesion/barrier layer helps to prevent diffusion of the contact metals into the surrounding dielectric. Suitable conductive fill metals 1922 include, but are not limited to, Cu, W, Ru and/or Co. The adhesion/barrier layer 1920 and conductive fill metal 1922 can be deposited into the contact trenches 1904 using a process such as evaporation, sputtering, ALD, CVD or electrochemical plating. Additionally, a seed layer (not shown) can be deposited into and lining the contact trenches 1904 prior to metal deposition, i.e., to facilitate plating of the metal. Following deposition, excess metal can be removed using a process such as CMP.

As highlighted above, of particular concern is the reliability of the dielectric material in between the source/drain contacts 1602 and the gate contacts 1908 such as dielectric fill material 1802. See arrow 1930. As such, it is the (breakdown/leakage) properties of this dielectric fill material 1802 that the present reliability test macro will be used to analyze. This concept is further illustrated by way of reference to FIG. 20 which provides a three-dimensional schematic view of one of the source/drain contacts 1602/gate contacts 1908, and the dielectric fill material 1802 therebetween. Components such as the ILD 1902 are not shown in FIG. 20 for ease and clarity of depiction. As shown in FIG. 20, a voltage V is applied to the gate contacts 1908 and the current, if any, between the source/drain contacts 1602 and gate contacts 1908 (i.e., due to breakdown or leakage of the intervening dielectric fill material 1802) is detected at the source/drain contacts 1602. For instance, the present COAG test macro can be used to analyze whether the thickness, composition, etc. of the dielectric fill material 1802 in a given design and associated manufacturing process is robust enough, or whether it breaks down or becomes too leaky. A detailed description of the process for reliability testing using the present COAG test macro is provided in conjunction with the description of FIG. 22, below.

In this example, the source/drain contacts 1602 are accessed from the top of the COAG test structure over the source/drain regions 304 in a top source/drain contact configuration. For instance, see FIG. 20 where both the source/drain contacts 1602 and gate contacts 1908 are accessed from the same (top) side of the COAG test structure. As provided above, the implementation of a top source/drain contact configuration is merely an example, and configurations are contemplated herein where the source/drain contacts are accessed from the bottom of the COAG test structure—see, for example, FIG. 23 below.

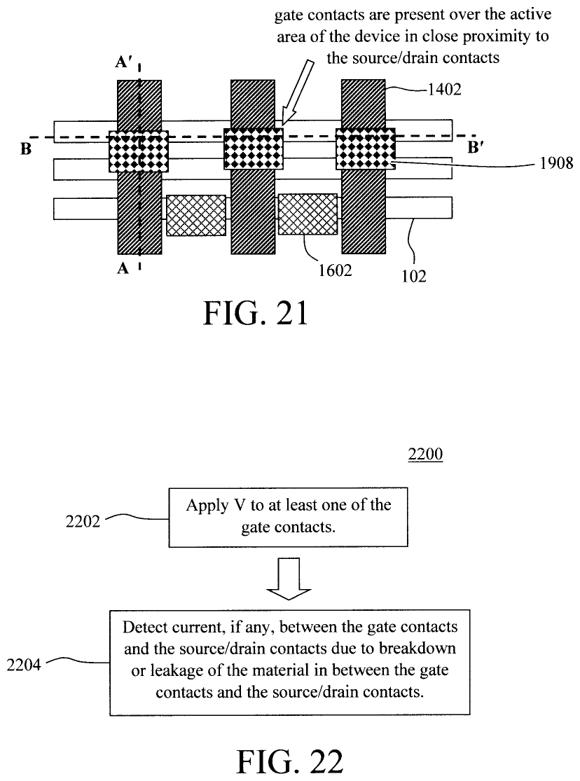

FIG. 21 is a top-down diagram (i.e., from viewpoint B—See FIG. 19) illustrating an orientation of the gate contacts 1908 and source/drain contacts 1602 relative to the fins 102 and gate-shaped dielectric structures 1402. For clarity, the intervening layers/structures such as the dielectric fill material 1802, ILD 1902, etc. are not shown in FIG. 21. The orientation of the cross-sectional views A-A′ and B-B′ are also shown in FIG. 21 for clarity. As shown in FIG. 21, the present reliability test macro implements a COAG design whereby the gate contacts 1908 are placed over the active area of the device. Doing so, however, places the gate contacts 1908 in close proximity to the source/drain contacts 1602. Advantageously, the present COAG test macro can be used to evaluate the reliability of this design.

An exemplary method for evaluating a COAG layout design using the present reliability test macros is now described by way of reference to methodology 2200 of FIG. 22. Methodology 2200 can be performed using any of the COAG reliability test macros described herein including the COAG reliability test macro described in conjunction with the description of FIGS. 1-21, above and/or the COAG test macro described in conjunction with the description of FIG. 23, below.

In step 2202, a voltage V is applied to at least one of the gate contacts (see, e.g., gate contacts 1108 in FIG. 12 or gate contacts 1908 in FIG. 20 and FIG. 23). Namely, embodiments are contemplated herein where the voltage V is applied in step 2202 to a single one of the gate contacts 1108/1908, a subset(s) of the gate contacts 1108/1908, or all of the gate contacts 1108/1908.

In step 2204, the current, if any, between the gate contacts (see, e.g., gate contacts 1108 in FIG. 12 or gate contacts 1908 in FIG. 20 and FIG. 23) and the source/drain contacts (see, e.g., source/drain contacts 802 in FIG. 12, source/drain contacts 1602 in FIG. 20 or source/drain contacts 2302 in FIG. 23) due to breakdown or leakage of the dielectric fill material (see, e.g., dielectric fill material 1002 in FIG. 12 or dielectric fill material 1802 in FIG. 20 and FIG. 23) is detected. By way of example only, the current between the gate contacts 1108/1908 and the source/drain contacts 802/1602/2302 can be detected at the source/drain contacts 802/1602/2302. Detecting the current between the gate contacts 1108/1908 and the source/drain contacts 802/1602/2302 in this manner can be used as a breakdown voltage (VBD) test or time-dependent dielectric breakdown (TDDB) test or leakage monitor of the COAG layout design. For instance, as described above, in the present COAG layout designs, the dielectric fill material 1002/1802 is present in between the gate contacts 1108/1908 and the source/drain contacts 802/1602/2302. If not robust enough, conductive paths can form through the dielectric fill material 1002/1802 (breakdown). Breakdown of the dielectric fill material 1002/1802 leads to an increase in the leakage current of the device.

For TDDB testing, the leakage current can be monitored in step 2204 to determine how leaky the dielectric fill material 1002/1802 is. For VBD testing, a process such as that described in U.S. Pat. No. 6,602,729 issued to Lin, entitled “Pulse Voltage Breakdown (VBD) Technique for Inline Gate Oxide Reliability Monitoring” can be employed to determine the robustness of the dielectric fill material 1002/1802. For instance, by way of example only, a reference current can be set that is below a breakdown current of the dielectric fill material 1002/1802. A stress voltage can then be applied to the gate contacts 1108/1908 in step 2202 that is below a breakdown voltage of the dielectric fill material 1002/1802. A resulting stress current can be monitored in step 2204. The stress voltage applied to the gate contacts 1108/1908 is then incrementally increased until the resulting stress current exceeds the reference current. If breakdown of the dielectric fill material 1002/1802 is detected, adjustments can be made to the COAG layout design such as increasing the thickness of the dielectric fill material 1002/1802 in between the gate contacts 1108/1908 and the source/drain contacts 802/1602/2302.

As provided above, the implementation of source/drain contacts that are accessed from the top of the COAG test structure over the source/drain regions 304 (such as source/drain contacts 802 and 1602 in the preceding examples) is merely one exemplary configuration, and embodiments are contemplated herein where the source/drain contacts are instead accessed from the bottom of the COAG test structure in what is referred to herein as a ‘bottom source/drain contact configuration.’ See, for example, FIG. 23 which provides a three-dimensional schematic view of an alternative embodiment of the present COAG test structure which employs a bottom source/drain contact 2302. The configuration of the other structures such as the gate contacts, dielectric fill material, etc. remains unchanged from the preceding example, and thus these structures are numbered alike in FIG. 23.

Namely, FIG. 23 depicts one (bottom) source/drain contact 2302/gate contact 1908, and the dielectric fill material 1802 therebetween. Components such as the ILD 1902 are not shown in FIG. 23 for ease and clarity of depiction. As shown in FIG. 23, the source/drain contact 2302 extends below the source/drain regions 304 over an (optional) dielectric 1304, e.g., SiOx. With this configuration, the source/drain contact 2302 can be accessed from the bottom of the COAG test structure, e.g., via additional wiring such as a buried power rail (not shown).

As with the previous examples, a voltage V is applied to the gate contacts 1908 and the current, if any, between the source/drain contacts 2302 and gate contacts 1908 (i.e., due to breakdown or leakage of the intervening dielectric fill material 1802) is detected at the source/drain contacts 2302 (from the bottom of the COAG test macro). For instance, as described in conjunction with the description of FIG. 22 above, the present COAG test macro can be used to analyze whether the thickness, composition, etc. of the dielectric fill material 1802 in a given design and associated manufacturing process is robust enough, or whether it breaks down or becomes too leaky.

Although illustrative embodiments of the present invention have been described herein, it is to be understood that the invention is not limited to those precise embodiments, and that various other changes and modifications may be made by one skilled in the art without departing from the scope of the invention.

What is claimed is:

1. A contact over active gate (COAG) layout design reliability test macro, comprising:
gate-shaped dielectric structures disposed over an active area of a substrate;
source/drain regions present on opposite sides of the gate-shaped dielectric structures;
source/drain contacts in direct contact with the source/drain regions;
a dielectric fill material disposed on the source/drain contacts; and
gate contacts present over, and in direct contact with, the gate-shaped dielectric structures in the active area, wherein the dielectric fill material is present in between the gate contacts and the source/drain contacts.

2. The COAG layout design reliability test macro of claim 1, further comprising:
isolation regions in the active area below the gate-shaped dielectric structures.

3. The COAG layout design reliability test macro of claim 2, wherein the isolation regions comprise a same material as the gate-shaped dielectric structures.

4. The COAG layout design reliability test macro of claim 1, wherein the gate-shaped dielectric structures comprise a material selected from the group consisting of: silicon oxide (SiOx), silicon nitride (SiN), and combinations thereof.

5. The COAG layout design reliability test macro of claim 1, further comprising:
gate spacers disposed alongside the gate-shaped dielectric structures, wherein the gate spacers offset the source/drain regions from the gate-shaped dielectric structures.

6. The COAG layout design reliability test macro of claim 1, wherein the gate spacers comprise a material selected from the group consisting of: as SiOx, silicon oxycarbide (SiOC), SiN, silicon-boron-nitride (SiBN), siliconborocarbonitride (SiBCN), silicon oxycarbonitride (SiOCN), and combinations thereof.

7. The COAG layout design reliability test macro of claim 1, wherein the source/drain contacts are present over the source/drain regions.

8. The COAG layout design reliability test macro of claim 1, wherein the source/drain contacts extend below the source/drain regions.

9. The COAG layout design reliability test macro of claim 1, wherein the dielectric fill material is selected from the group consisting of: SiOx, silicon carbide (SiC), SiOCN, SiN, organosilicate glass (SiCOH), and combinations thereof.

10. The COAG layout design reliability test macro of claim 1, wherein the dielectric fill material has a thickness t of from about 5 nm to about 30 nm.

11. The COAG layout design reliability test macro of claim 1, wherein the active area comprises fins present on the substrate.

12. A method of forming a contact over active gate (COAG) layout design reliability test macro, the method comprising:
forming sacrificial gates over an active area of a substrate;
forming source/drain regions on opposite sides of the sacrificial gates;
burying the sacrificial gates and the source/drain regions in an interlayer dielectric (ILD);
selectively removing the sacrificial gates forming gate trenches in the ILD;
forming gate-shaped dielectric structures in the gate trenches;
forming source/drain contacts in direct contact with the source/drain regions;
depositing a dielectric fill material onto the source/drain contacts; and
forming gate contacts over, and in direct contact with, the gate-shaped dielectric structures in the active area, wherein the dielectric fill material is present in between the gate contacts and the source/drain contacts.

13. The method of claim 12, further comprising:
forming gate spacers alongside the sacrificial gates.

14. The method of claim 12, further comprising:
creating cuts in the active area below the gate trenches; and
forming isolation regions in the cuts below the gate-shaped dielectric structures.

15. The method of claim 14, wherein the isolation regions comprise a same material as the gate-shaped dielectric structures.

16. The method of claim 12, wherein the gate-shaped dielectric structures comprise a material selected from the group consisting of: silicon oxide (SiOx), silicon nitride (SiN), and combinations thereof.

17. The method of claim 12, wherein the sacrificial gates comprise a material selected from the group consisting of: poly-silicon (poly-Si), amorphous silicon (a-Si), and combinations thereof.

18. The method of claim 12, further comprising:
patterning fins in the active area of the substrate, wherein the sacrificial gates are formed over, and oriented perpendicular to, the fins.

19. A method of evaluating a contact over active gate (COAG) layout design, the method comprising:
providing a reliability test macro comprising:
gate-shaped dielectric structures disposed over an active area of a substrate;
source/drain regions present on opposite sides of the gate-shaped dielectric structures;
source/drain contacts in direct contact with the source/drain regions;
a dielectric fill material disposed on the source/drain contacts;
gate contacts present over, and in direct contact with, the gate-shaped dielectric structures in the active area, wherein the dielectric fill material is present in between the gate contacts and the source/drain contacts;
applying a voltage V to at least one of the gate contacts; and
detecting current between the gate contacts and the source/drain contacts due to breakdown or leakage of the dielectric fill material.

20. The method of claim 19, wherein the reliability test macro further comprises:
isolation regions in the active area below the gate-shaped dielectric structures, wherein the isolation regions comprise a same material as the gate-shaped dielectric structures.
